(19) United States
(12) Patent Application Publication
(10) Pub. No.: US 2025/0104998 A1
(43) Pub. Date: Mar. 27, 2025

(54) PROCESSING METHOD, METHOD OF MANUFACTURING SEMICONDUCTOR DEVICE, PROCESSING APPARATUS, AND RECORDING MEDIUM

(71) Applicant: Kokusai Electric Corporation, Tokyo (JP)

(72) Inventors: Shoma MIYATA, Toyama-shi (JP); Kimihiko NAKATANI, Toyama-shi (JP); Motomu DEGAI, Toyama-shi (JP)

(73) Assignee: Kokusai Electric Corporation, Tokyo (JP)

(21) Appl. No.: 18/887,572

(22) Filed: Sep. 17, 2024

(30) Foreign Application Priority Data
Sep. 22, 2023 (JP) 2023-159104

(51) Int. Cl. H01L 21/02; C23C 16/04; C23C 16/30; C23C 16/40; C23C 16/455; C23C 16/52; C23C 16/56; H01L 21/311

(52) U.S. Cl. CPC H01L 21/02164; C23C 16/042; C23C 16/30; C23C 16/401; C23C 16/45544; C23C 16/52; C23C 16/56; H01L 21/02126; H01L 21/0228; H01L 21/31111

(57) ABSTRACT

There is provided a technique that includes: (a) forming a first film containing a first element and a second element on a surface of a first base by supplying a first film-forming agent to a substrate including the first base and a second base; (b) forming an inhibitor layer on the first film by supplying a modifying agent to the substrate and causing at least a portion of molecular structures of molecules constituting the modifying agent to be adsorbed on the first film; and (c) forming a second film containing the first element and the second element on a surface of the second base by supplying a second film-forming agent to the substrate with the inhibitor layer formed on the first film.

### CROSS-REFERENCE TO RELATED APPLICATION

This application is based upon and claims the benefit of priority from Japanese Patent Application No. 2023-159104, filed on Sep. 22, 2023, the entire contents of which are incorporated herein by reference.

### TECHNICAL FIELD

The present disclosure relates to a processing method, a method of manufacturing a semiconductor device, a processing apparatus, and a recording medium.

### BACKGROUND

In the related art, as a process of manufacturing a semiconductor device, there is sometimes a process in which a film is selectively grown and formed on a specific surface among multiple types of surfaces made of different materials exposed on a substrate surface (hereinafter referred to as a “selective growth” or a “selective film formation”).

### SUMMARY

According to some embodiments of the present disclosure, there is provided a technique of selectively forming a film on a desired surface with high precision.

According to some embodiments of the present disclosure, there is provided a technique that includes: (a) forming a first film containing a first element and a second element on a surface of a first base by supplying a first film-forming agent to a substrate including the first base and a second base; (b) forming an inhibitor layer on the first film by supplying a modifying agent to the substrate and causing at least a portion of molecular structures of molecules constituting the modifying agent to be adsorbed on the first film; and (c) forming a second film containing the first element and the second element on a surface of the second base by supplying a second film-forming agent to the substrate with the inhibitor layer formed on the first film.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a processing apparatus suitably used in some embodiments of the present disclosure, in which a portion of the process furnace is shown in a vertical cross-sectional view.

FIG. 2 is a schematic configuration diagram of the vertical process furnace of the processing apparatus suitably used in some embodiments of the present disclosure, in which a portion of the process furnace is shown in a cross-sectional view taken along line A-A of FIG. 1.

FIG. 3 is a schematic configuration diagram of a controller of a processing apparatus suitably used in some embodiments of the present disclosure, in which a control system of the controller is shown in a block diagram.

FIG. 4A is a cross-sectional schematic diagram illustrating a surface of a wafer including a first base and a second base on a surface of the wafer. FIG. 4B is a schematic cross-sectional diagram illustrating the surface of the wafer after selectively forming a first film on a surface of the first base, by performing Step A from a state of FIG. 4A. FIG. 4C is a schematic cross-sectional diagram illustrating the surface of the wafer after forming an inhibitor layer on a surface of the first film formed on the surface of the first base, by performing Step B from a state of FIG. 4B. FIG. 4D is a schematic cross-sectional diagram illustrating the surface of the wafer after selectively forming a second film on a surface of the second base, by performing Step C from a state of FIG. 4C. FIG. 4E is a schematic cross-sectional diagram illustrating the surface of the wafer after removing the first film formed on the surface of the first base together with the inhibitor layer, by performing Step D from a state of FIG. 4D.

FIGS. 5A to 5D are diagrams similar to FIGS. 4A to 4D, respectively. FIG. 5E is a schematic cross-sectional diagram illustrating the surface of the wafer after selectively forming a third film on a surface of the second film formed on the surface of the second base, by performing Step E from a state of FIG. 5D. FIG. 5F is a schematic cross-sectional diagram illustrating the surface of the wafer after removing the first film formed on the surface of the first base together with the inhibitor layer, by performing Step D from a state of FIG. 5E.

### DETAILED DESCRIPTION

### Embodiments of Present Disclosure

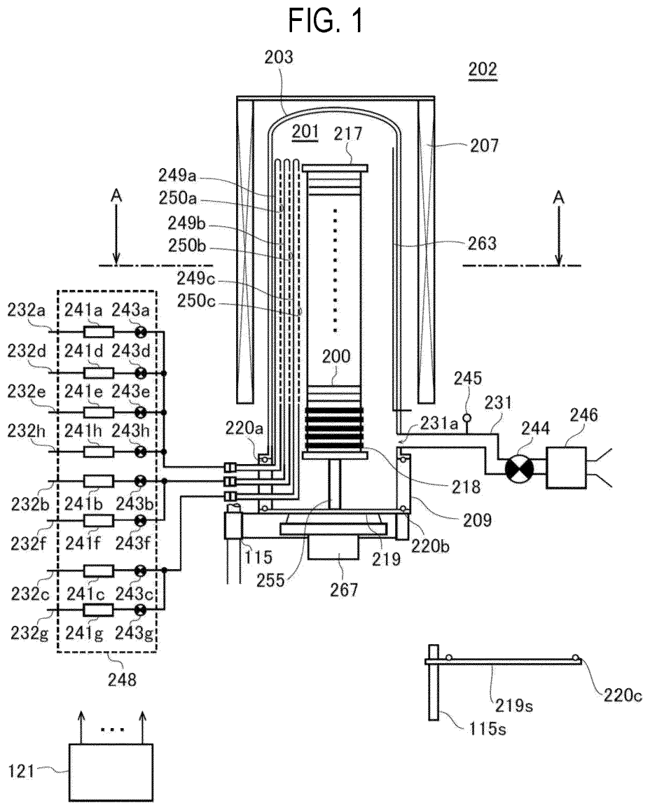

Hereinafter, some embodiments of the present disclosure will be described mainly with reference to FIGS. 1 to 3 and FIGS. 4A to 4E. The drawings used in the following description are schematic, and dimensional relationships, ratios, and the like of the respective components shown in the drawings may not match the actual ones. Further, dimensional relationships, ratios, and the like of the respective components among plural drawings may not match one another.

### (1) Configuration of Processing Apparatus (Processing System)

As illustrated in FIG. 1, a process furnace 202 of a processing apparatus includes a heater 207 serving as a temperature regulator (heating part). The heater 207 is formed in a cylindrical shape and is mounted vertically by being supported by a holding plate. The heater 207 functions as an energy provider configured to provide energy to a gas, and also functions as an activator (exciter) when the gas is thermally activated (excited).

A reaction tube 203 is arranged inside the heater 207 so as to be concentric with the heater 207. The reaction tube 203 is made of, for example, a heat-resistant material such as quartz (SiO₂) or silicon carbide (SiC) and is formed in a cylinder shape with a closed upper end and an open lower end. A manifold 209 is arranged to be concentric with the reaction tube 203 under the reaction tube 203. The manifold 209 is made of, for example, metal material such as stainless steel (SUS), and is formed in a cylindrical shape with open upper and lower ends. The upper end of the manifold 209 is configured to be engaged with the lower end of the reaction tube 203, thus supporting the reaction tube 203. An O-ring 220a is provided as a seal between the manifold 209 and the reaction tube 203. The reaction tube 203 is vertically installed, similar to the heater 207. A process container (reaction container) mainly includes the reaction tube 203 and the manifold 209. A process chamber 201 is formed in a hollow cylindrical area of the process container. The process chamber 201 is configured to be capable of accommodating a wafer 200 serving as a substrate. The wafer 200 is processed inside the process chamber 201.

Nozzles 249a to 249c as first to third suppliers are installed in the process chamber 201 to penetrate a sidewall of the manifold 209, respectively. The nozzles 249a to 249c are also referred to as first to third nozzles, respectively. The nozzles 249a to 249c are made of, for example, a heat-resistant material such as quartz or SiC. Gas supply pipes 232a to 232c are connected to the nozzles 249a to 249c, respectively. The nozzles 249a to 249c are different nozzles, respectively, and each of the nozzles 249a and 249c is installed adjacent to the nozzle 249b.

Mass flow controllers (MFCs) 241a to 241c serving as flow rate controllers (flow rate control parts), and valves 243a to 243c serving as opening/closing valves, are installed at the gas supply pipes 232a to 232c, respectively, sequentially from the upstream side of gas flow. Gas supply pipes 232d, 232e, and 232h are each connected to the gas supply pipe 232a at the downstream side of the valve 243a. Gas supply pipes 232f and 232g are connected to the gas supply pipes 232b and 232c at the downstream side of the valves 243b and 243c, respectively. The gas supply pipes 232d to 232h are provided with MFCs 241d to 241h and valves 243d to 243h, respectively, sequentially from the upstream side of gas flow. The gas supply pipes 232a to 232h are made of, for example, a metal material such as SUS.

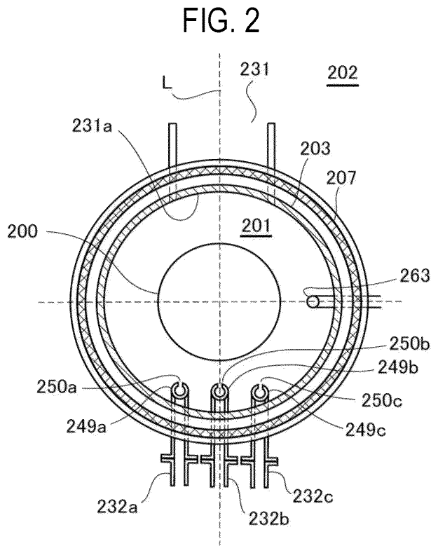

As illustrated in FIG. 2, the nozzles 249a to 249c are each arranged in an annular space (in a plane view) between an inner wall of the reaction tube 203 and the wafer 200 to extend upward from a lower side to an upper side of the inner wall of the reaction tube 203, that is, along an arrangement direction of the wafers 200. In other words, the nozzles 249a to 249c are each installed at a region horizontally surrounding a wafer arrangement region in which the wafers 200 are arranged at the lateral side of the wafer arrangement region, along the wafer arrangement region. In a plane view, the nozzle 249b is disposed to face an exhaust port 231a, which will be described later, on a straight line with a center of the wafer 200 loaded into the process chamber 201 being interposed between the nozzle 249b and the exhaust port 231a. The nozzles 249a and 249c are disposed to sandwich a straight line L passing through the nozzle 249b and a center of the exhaust port 231a from both sides along the inner wall of the reaction tube 203 (outer periphery of the wafer 200). The straight line L is also a straight line passing through the nozzle 249b and the center of the wafer 200. In other words, it may also be said that the nozzle 249c is installed at an opposite side of the nozzle 249a with the straight line L interposed therebetween. The nozzles 249a and 249c are arranged in line symmetry with the straight line L as an axis of symmetry. Gas supply holes 250a to 250c configured to supply a gas are formed at side surfaces of the nozzles 249a to 249c, respectively. The gas supply holes 250a to 250c are each opened to oppose (face) the exhaust port 231a in a plane view, and is configured to be capable of supplying the gas toward the wafer 200. A plurality of gas supply holes 250a to 250c are formed from the lower side to the upper side of the reaction tube 203.

Precursors, i.e., a first precursor, a second precursor, and a third precursor, are supplied from the gas supply pipe 232a into the process chamber 201 via the MFC 241a, valve 243a, and nozzle 249a. The first precursor is used as a first film-forming agent. The second precursor is used as a second film-forming agent. The third precursor is used as a third film-forming agent.

Catalysts, i.e., a first catalyst, a second catalyst, and a third catalyst, are supplied from the gas supply pipe 232b into the process chamber 201 via the MFC 241b, valve 243b, and nozzle 249b. The first catalyst is used as a first film-forming agent. The second catalyst is used as a second film-forming agent. The third catalyst is used as a third film-forming agent.

Oxidizing agents, i.e., a first oxidizing agent, a second oxidizing agent, and a third oxidizing agent, are supplied from the gas supply pipe 232c into the process chamber 201 via the MFC 241c, valve 243c, and nozzle 249c. The first oxidizing agent is used as a first film-forming agent. The second oxidizing agent is used as a second film-forming agent. The third oxidizing agent is used as a third film-forming agent.

A modifying agent is supplied from the gas supply pipe 232d into the process chamber 201 via the MFC 241d, valve 243d, gas supply pipe 232a, and nozzle 249a.

An etching agent is supplied from the gas supply pipe 232h into the process chamber 201 via the MFC 241h, valve 243h, gas supply pipe 232a, and nozzle 249a.

An inert gas is supplied from the gas supply pipes 232e to 232g into the process chamber 201 via the MFCs 241e to 241g, valves 243e to 243g, gas supply pipes 232a to 232c, and nozzles 249a to 249c. The inert gas acts as a purge gas, a carrier gas, a dilution gas, and the like.

A precursor supply system (first precursor supply system, second precursor supply system, and third precursor supply system) mainly includes the gas supply pipe 232a, MFC 241a, and valve 243a. A catalyst supply system (first catalyst supply system, second catalyst supply system, and third catalyst supply system) mainly includes the gas supply pipe 232b, MFC 241b, and valve 243b. An oxidizing agent supply system (first oxidizing agent supply system, second oxidizing agent supply system, and third oxidizing agent supply system) mainly includes the gas supply pipe 232c, MFC 241c, and valve 243c. The precursor supply system (first precursor supply system, second precursor supply system, and third precursor supply system), the catalyst supply system (first catalyst supply system, second catalyst supply system, and third catalyst supply system), and the oxidizing agent supply system (first oxidizing agent supply system, second oxidizing agent supply system, and third oxidizing agent supply system) are also referred to as film-forming agent supply systems (first film-forming agent supply system, second film-forming agent supply system, and third film-forming agent supply system). A modifying agent supply system mainly includes the gas supply pipe 232d, MFC 241d, and valve 243d. An etching agent supply system mainly includes the gas supply pipe 232h, MFC 241h, and valve 243h. An inert gas supply system mainly includes the gas supply pipes 232e to 232g, MFCs 241e to 241g, and valves 243e to 243g.

One or the entirety of the various supply systems described above may be constituted as an integrated supply system 248 where the valves 243a to 243h, MFCs 241a to 241h, and the like are integrated. The integrated supply system 248 is connected to each of the gas supply pipes 232a to 232h, and is configured such that operations of supplying various substances (various gases) into the gas supply pipes 232a to 232h such as the opening/closing operations of the valves 243a to 243h and the flow rate regulating operations by the MFCs 241a to 241h are controlled by a controller 121, which will be described later. The integrated supply system 248 is constituted as an integral-type or detachable-type integrated unit, and may be attached to or detached from the gas supply pipes 232a to 232h and the like on an integrated unit basis, such that maintenance, replacement, extension, and the like of the integrated supply system 248 may be performed on an integrated unit basis.

The exhaust port 231a configured to exhaust an internal atmosphere of the process chamber 201 is provided below the sidewall of the reaction tube 203. As illustrated in FIG. 2, in a plane view, the exhaust port 231a is positioned to oppose (face) the nozzles 249a to 249c (gas supply holes 250a to 250c) with the wafers 200 interposed therebetween. The exhaust port 231a may be provided from the lower side to the upper side of the sidewall of the reaction tube 203, that is, along the wafer arrangement region. An exhaust pipe 231 is connected to the exhaust port 231a. A vacuum pump 246 as a vacuum exhauster is connected to the exhaust pipe 231 via a pressure sensor 245, which serves as a pressure detector (pressure detecting part) configured to detect an internal pressure of the process chamber 201, and an auto pressure controller (APC) valve 244, which serves as a pressure regulator (pressure regulating part). The APC valve 244 is configured to be capable of performing or stopping a vacuum exhaust operation in the process chamber 201 by opening or closing the valve while the vacuum pump 246 is actuated, and is also configured to be capable of regulating the internal pressure of the process chamber 201 by adjusting an opening state of the valve based on pressure information detected by the pressure sensor 245 while the vacuum pump 246 is actuated. An exhaust system mainly includes the exhaust pipe 231, APC valve 244, and pressure sensor 245. The exhaust system may include the vacuum pump 246.

A seal cap 219, which serves as a furnace opening lid configured to be capable of airtightly sealing a lower end opening of the manifold 209, is provided under the manifold 209. The seal cap 219 is made of, for example, metal material such as SUS, and is formed in a disc shape. An O-ring 220b, which serves as a seal making contact with the lower side of the manifold 209, is provided at an upper surface of the seal cap 219. A rotator 267 configured to rotate a boat 217, which will be described later, is installed under the seal cap 219. A rotary shaft 255 of the rotator 267 is connected to the boat 217 through the seal cap 219. The rotator 267 is configured to rotate the wafer 200 by rotating the boat 217. The seal cap 219 is configured to be vertically raised or lowered by a boat elevator 115, which serves as an elevator installed outside the reaction tube 203. The boat elevator 115 is constituted as a transport apparatus (transporter) configured to load or unload (transport) the wafer 200 into or out of the process chamber 201 by raising or lowering the seal cap 219.

A shutter 219s, which serves as a furnace opening lid configured to be capable of airtightly sealing a lower end opening of the manifold 209 in a state where the seal cap 219 is lowered and the boat 217 is unloaded from the process chamber 201, is provided under the manifold 209. The shutter 219s is made of, for example, metal material such as SUS, and is formed in a disc shape. An O-ring 220c, which serves as a seal making contact with the lower end of the manifold 209, is provided at an upper surface of the shutter 219s. The opening/closing operation (such as elevating and rotating operations) of the shutter 219s is controlled by a shutter opening/closing mechanism 115s.

The boat 217, which serves as a substrate support, is configured to support a plurality of wafers 200, e.g., 25 to 200 wafers in such a state that the wafers 200 are arranged at intervals in a horizontal posture and in multiple stages along a vertical direction with the centers of the wafers 200 aligned with one another. The boat 217 is made of, for example, a heat-resistant material such as quartz or SiC. Heat insulating plates 218, which are made of, for example, a heat-resistant material such as quartz or SiC, are supported in multiple stages at a lower side of the boat 217.

A temperature sensor 263 is installed as a temperature detector inside the reaction tube 203. An internal temperature of the process chamber 201 falls within a desired temperature distribution by regulating a state of supplying electric power to the heater 207 based on temperature information detected by the temperature sensor 263. The temperature sensor 263 is provided along the inner wall of the reaction tube 203.

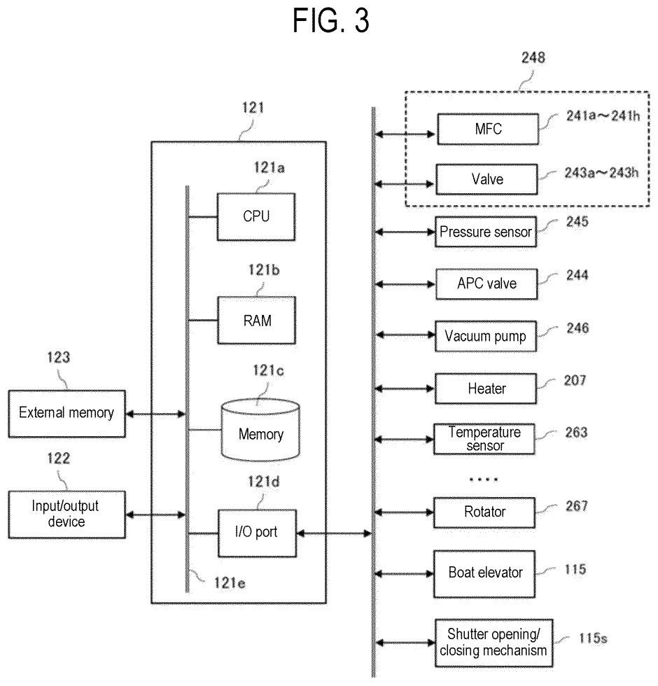

As illustrated in FIG. 3, the controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 including, for example, a touch panel or the like, is connected to the controller 121. Further, an external memory 123 may be connected to the controller 121. In addition, the processing apparatus may be configured to include one controller, or may be configured to include a plurality of controllers. In other words, a control to perform a processing sequence to be described later may be performed by using a single controller, or may be performed by using a plurality of controllers. Further, the plurality of controllers may be constituted as a control system by being connected to each other through wired or wireless communication networks, and the control to perform the processing sequence to be described later may be performed by the entire control system. When the term “controller” is used herein, it may refer to one controller, a plurality of controllers, or a control system constituted by a plurality of controllers.

The memory 121c includes, for example, a flash memory, a hard disk drive (HDD), a solid state drive (SSD), or the like. A control program that controls an operation of a processing apparatus, a process recipe in which sequences, conditions, and the like of processing to be described later are written, and the like are readably stored in the memory 121c. The process recipe functions as a program that is combined to cause, by the controller 121, the processing apparatus (processing system) to perform each sequence in the processing to be described later, to obtain a predetermined result. Hereinafter, the process recipe, the control program, and the like are generally and simply referred to as a “program.” Further, the process recipe may be simply referred to as a “recipe.” When the term “program” is used herein, it may refer to a case of including the recipe, a case of including the control program, or a case of including both the recipe and the control program. The RAM 121b is constituted as a memory area (work area) where programs, data, and the like read by the CPU 121a are temporarily stored.

The I/O port 121d is connected to the above-described MFCs 241a to 241h, valves 243a to 243h, pressure sensor 245, APC valve 244, vacuum pump 246, temperature sensor 263, heater 207, rotator 267, boat elevator 115, shutter opening/closing mechanism 115s, and the like.

The CPU 121a is configured to be capable of reading and executing the control program from the memory 121c and reading the recipe from the memory 121c in response to, e.g., an input of an operation command from the input/output device 122. The CPU 121a is configured to be capable of controlling the flow rate regulating operation of various substances (gases) by the MFCs 241a to 241h, the opening/closing operation of the valves 243a to 243h, the pressure regulating operation performed by the APC valve 244 based on the opening/closing operation of the APC valve 244 and the pressure sensor 245, the actuating and stopping operation of the vacuum pump 246, the temperature regulating operation performed by the heater 207 based on the temperature sensor 263, the operation of rotating the boat 217 and adjusting a rotational speed of the boat 217 with the rotator 267, the operation of moving the boat 217 up or down by the boat elevator 115, the opening/closing operation of the shutter 219s by the shutter opening/closing mechanism 115s, and the like, according to contents of the read recipe.

The controller 121 may be configured by installing, in the computer, the above-described program recorded and stored in the external memory 123. Examples of the external memory 123 may include a magnetic disk such as a HDD, an optical disc such as a CD, a magneto-optical disc such as a MO, a semiconductor memory such as a USB memory or a SSD, and the like. The memory 121c and the external memory 123 are constituted as a computer-readable recording medium. Hereinafter, the memory 121c and the external memory 123 may be generally and simply referred to as a “recording medium.” When the term “recording medium” is used herein, it may refer to a case of including the memory 121c, a case of including the external memory 123, or a case of including both the memory 121c and the external memory 123. Further, the program may be provided to the computer by using a communication means or unit such as the Internet or a dedicated line, instead of using the external memory 123.

### (2) Processing Step

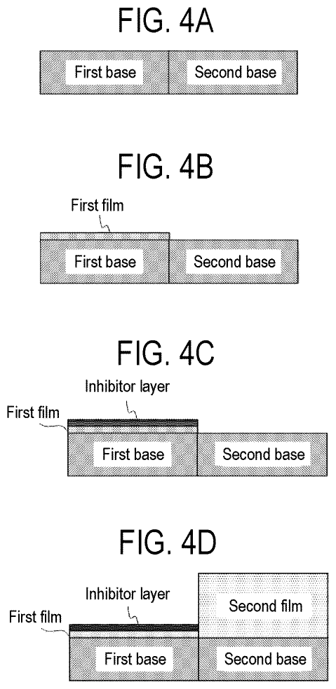

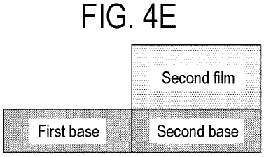

As a process (a method) of manufacturing a semiconductor device by using the above-described processing apparatus, an example of a method of processing a substrate (a processing method), i.e., an example of a processing sequence of selectively forming a film on a surface of a second base, among first and second bases on a surface of the wafer 200 as a substrate, will be described mainly with reference to FIGS. 4A to 4E. In the following description, an operation of each component constituting the processing apparatus is controlled by the controller 121. In addition, the processing apparatus is also referred to as a substrate processing apparatus, a film formation processing apparatus, or a film-forming apparatus. Further, the processing method is also referred to as a method of processing a substrate, a film formation processing method, or a film-forming method.

In addition, the wafer 200 as a substrate includes a first base and a second base on a surface thereof, as illustrated in FIG. 4A. In the following description, for convenience, a case where the first base is a silicon nitride film (SiN film) and the second base is a silicon film (Si film) will be described as a representative example.

A processing sequence of the embodiments of the present disclosure includes the following steps:
(a) forming a first film containing a first element and a second element on a surface of a first base by supplying a first film-forming agent to a wafer 200 including the first base and a second base (Step A);
(b) forming an inhibitor layer on the first film by supplying a modifying agent to the wafer 200 and causing at least a portion of molecular structures of molecules constituting the modifying agent to be adsorbed on the first film (Step B); and
(c) forming a second film containing the first element and the second element on a surface of the second base by supplying a second film-forming agent to the wafer 200 with the inhibitor layer formed on the first film (Step C).

Hereinafter, a case where in Step A, a first precursor, a first oxidizing agent, and a first catalyst are supplied as the first film-forming agent to the wafer 200, and in Step C, a second precursor, a second oxidizing agent, and a second catalyst are supplied as the second film-forming agent to the wafer 200 will be described. Specifically, a case where in Step A, a cycle which includes (a1) supplying the first precursor and the first catalyst to the wafer 200 (Step A1) and (a2) supplying the first oxidizing agent and the first catalyst to the wafer 200 (Step A2) is performed a predetermined number of times (m times, where m is an integer of 1 or 2 or more), and in Step C, a cycle which includes (c1) supplying the second precursor and the second catalyst to the wafer 200 (Step C1) and (c2) supplying the second oxidizing agent and the second catalyst to the wafer 200 (Step C2) is performed a predetermined number of times (n times, where n is an integer of 1 or 2 or more) will be described.

In addition, in at least one selected from the group of Step A1 and Step A2, the supply of the first catalyst may be omitted depending on a processing condition, and in at least one selected from the group of Step C1 and Step C2, the supply of the second catalyst may also be omitted. For example, the supply of the first catalyst may be omitted in Step A1, the supply of the first catalyst may be omitted in Step A2, and the supply of the first catalyst may be omitted in each of Step A1 and Step A2. For example, in this step, the first precursor and the first oxidizing agent may be used as the first film-forming agent. Further, for example, the supply of the second catalyst may be omitted in Step C1, the supply of the second catalyst may be omitted in Step C2,and the supply of the second catalyst may be omitted in each of Step C1 and Step C2. For example, in this step, the second precursor and the second oxidizing agent may be used as the second film-forming agent.

In addition, in the following example, a case where the processing sequence further includes (d) removing the first film by supplying an etching agent to the wafer 200 after the formation of the second film on the surface of the second base (step D) will be described. In addition, the processing performed in Step D is also simply referred to as an “etch-back.”

Herein, for convenience, the above-described processing sequence may also be represented as follows. The same notation is also used in the following description of modifications and other embodiments.

(First Precursor+First Catalyst→First Oxidizing Agent+First Catalyst)×m→Modifying Agent→(Second Precursor+Second Catalyst→Second Oxidizing Agent+Second Catalyst)×n→Etching Agent (Etch-Back)

When the term “wafer” is used in the present disclosure, it may refer to “a wafer itself” or “a stacked body of a wafer and certain layers or films formed on a surface of the wafer.” When the phrase “a surface of a wafer” is used in the present disclosure, it may refer to “a surface of a wafer itself” or “a surface of a certain layer formed on a wafer.” When the expression “a certain layer is formed on a wafer” is used in the present disclosure, it may mean that “a certain layer is formed directly on a surface of a wafer itself” or that “a certain layer is formed on a layer formed on a wafer.” When the term “substrate” is used in the present disclosure, it may be synonymous with the term “wafer.”

The term “layer” as used herein includes at least one selected from the group of a continuous layer and a discontinuous layer. For example, a first layer, a second layer, a third layer, a fourth layer, and an inhibitor layer may each include a continuous layer, a discontinuous layer, or both.

The term “agent” as used herein includes at least one selected from the group of gaseous substance and liquefied substance. The liquefied substance includes a mist-like substance. In other words, each of the first film-forming agent (first precursor, first oxidizing agent, and first catalyst), the second film-forming agent (second precursor, second oxidizing agent, and second catalyst), and the third film-forming agent (third precursor, third oxidizing agent, and third catalyst), the modifying agent, and the etching agent may include gaseous substance, liquefied substance such as mist-like substance, or both.

### Wafer Charging and Boat Loading

After the boat 217 is charged with a plurality of wafers 200 (wafer charging), the shutter 219s is moved by the shutter opening/closing mechanism 115s and the lower end opening of the manifold 209 is opened (shutter opening). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b. Thus, the wafers 200 are provided inside the process chamber 201.

### Pressure Regulation and Temperature Regulation

After the boat loading is completed, the inside of the process chamber 201, that is, a space where the wafers 200 are placed, is vacuum-exhausted (decompression-exhausted) by the vacuum pump 246 to reach a desired pressure (state of vacuum). In this operation, the internal pressure of the process chamber 201 is measured by the pressure sensor 245, and the APC valve 244 is feedback-controlled based on the measured pressure information. Further, the wafers 200 in the process chamber 201 are heated by the heater 207 to reach a desired processing temperature. In this operation, a state of supplying electric power to the heater 207 is feedback-controlled based on the temperature information detected by the temperature sensor 263 such that a temperature distribution in the process chamber 201 becomes a desired temperature distribution. Further, the rotation of the wafers 200 by the rotator 267 is started. The exhaust of the inside of the process chamber 201 and the heating and rotation of the wafers 200 are continuously performed at least until the processing on the wafers 200 is completed.

### Step A

Thereafter, by supplying a first film-forming agent to the wafer 200 including a first base and a second base on a surface thereof, a first film containing a first element and a second element is formed on a surface of the first base. In this step, specifically, the following Steps A1 and A2 are sequentially executed.

### {Step A1}

In this step, a first precursor and a first catalyst are supplied to the wafer 200.

Specifically, the valves 243a and 243b are opened to cause the first precursor and the first catalyst to flow through the gas supply pipes 232a and 232b, respectively. The first precursor and the first catalyst are regulated in flow rate by the MFCs 241a and 241b, respectively, and are supplied into the process chamber 201 via the nozzles 249a and 249b, respectively. The first precursor and the first catalyst are mixed inside the process chamber 201, and then are exhausted via the exhaust port 231a. At this time, the first precursor and the first catalyst are supplied to the wafer 200 from a lateral side of the wafer 200 (supply of first precursor+first catalyst). At this time, the valves 243e to 243g may be opened to supply an inert gas into the process chamber 201 via the respective nozzles 249a to 249c.

By supplying the first precursor and the first catalyst to the wafer 200 under a processing condition to be described later, it is possible to selectively (preferentially) chemisorb at least a portion of molecular structures of molecules constituting the first precursor on the surface of the first base among the surfaces of the first base and the second base. This allows a first layer to be selectively formed on the surface of the first base. The first layer contains at least a portion of molecular structures of molecules constituting the first precursor, which is a residue derived from the first precursor.

In this step, a property that an incubation time on the surface of the second base is longer than an incubation time on the surface of the first base when forming the first layer by using the first precursor, which is a first film-forming agent, is used to selectively form the first layer on the surface of the first base. A surface of a SiN film, which is the first base, contains NH terminations or OH terminations, while a surface of a Si film, which is the second base, contains H terminations. When forming the first layer, an incubation time on the H terminations in the surface of the Si film is longer than an incubation time on the NH terminations or OH terminations in the surface of the SiN film. In other words, it is more difficult to form the first layer on the surface of the Si film, which contains H terminations, than on the surface of the SiN film, which contains NH terminations or OH terminations. Therefore, in this step, it is possible to selectively (preferentially) form the first layer on the surface of the SiN film, which is the first base, rather than on the surface of the Si film, which is the second base. In addition, in this regard, it may be said that when attempting to form the first layer on the surface containing NH terminations, OH terminations, or H terminations, the H terminations or the surface containing the H terminations may cause a film formation inhibition effect (an adsorption inhibition effect or a reaction inhibition effect).

In addition, to reliably expose the H terminations on the surface of the Si film, which is the second base, the surface of the wafer 200 may be previously exposed to an etching agent such as an aqueous HF solution (DHF). A native oxide film may be formed on the surface of the Si film, which is the second base. In this case, by exposing the surface of the wafer 200 to the etching agent, the native oxide film on the surface of the Si film may be removed, thereby reliably exposing the H terminations on the surface of the Si film. In addition, a native oxide film may be formed on the surface of the SiN film, which is the first base. In this case, by exposing the surface of the wafer 200 to the etching agent, the native oxide film on the surface of the SiN film may also be removed, thereby allowing the NH terminations or OH terminations to be appropriately exposed on the surface of the SiN film. In addition, the etching agent may be the same as an etching agent used in Step D to be described later, and an etching process at this time may be carried out with the same processing sequence and processing condition as the etching processing in Step D to be described later.

A processing condition when the first precursor and the first catalyst are supplied in this step is exemplified as follows:
Processing temperature: room temperature (25 degrees C.) to 200 degrees C., specifically 25 to 150 degrees C.;
Processing pressure: 13 to 2,666 Pa, specifically 13 to 1,333 Pa;
Processing time: 1 to 90 seconds, specifically 1 to 60 seconds;
Supply flow rate of first precursor: 0.001 to 2 slm, specifically 0.001 to 1 slm;
Supply flow rate of first catalyst: 0.001 to 2 slm, specifically 0.001 to 1 slm; and
Supply flow rate of Inert gas (for each gas supply pipe): 0 to 20 slm.

In addition, notation of a numerical range such as “25 to 200 degrees C.” herein means that lower and upper limit values are included in that range. Therefore, for example, “25 to 200 degrees C.” means “25 degrees C. or more and 200 degrees C. or less.” The same applies to other numerical ranges. Further, the processing temperature herein means the temperature of the wafer 200 or the internal temperature of the process chamber 201, and the processing pressure herein means the internal pressure of the process chamber 201. Further, the processing time means a time during which a process is continued. Further, when 0 slm (sccm) is included in the supply flow rate, 0 slm (sccm) means a case where no gas is supplied. The same applies to the following description.

After the first layer is selectively formed on the surface of the first base, the valves 243a and 243b are closed to stop the supply of the first precursor and the first catalyst into the process chamber 201. Then, the interior of the process chamber 201 is vacuum-exhausted to remove gaseous substance and the like remaining in the process chamber 201 from the interior of the process chamber 201. At this time, the valves 243e to 243g are opened to supply an inert gas into the process chamber 201 via the nozzles 249a to 249c. The inert gas supplied from the nozzles 249a to 249c acts as a purge gas, thereby purging the interior of the process chamber 201 (purging).

A processing condition when the purging is performed in this step is exemplified as follows:
Processing pressure: 1 to 30 Pa;
Processing time: 1 to 120 seconds, specifically 1 to 60 seconds; and
Supply flow rate of inert gas (for each gas supply pipe): 0.5 to 20 slm

Further, the processing temperature during the purging may be the same as the processing temperature during the supply of the first precursor and the first catalyst.

As the first precursor, for example, a substance (gas) containing at least one selected from the group of an amino group, an alkoxy group, and a chloro group may be used. Further, the substance (gas) containing at least one selected from the group of an amino group, an alkoxy group, and a chloro group may be a substance (gas) containing silicon (Si). The first precursor may be selected depending on a type of the first base. For example, in a case where the first base is a film composed of a metal element, a substance (gas) containing an amino group and Si may be selected.

For example, a substance (gas) containing an amino group and Si such as tetrakis (dimethylamino) silane (Si[N(CH₃)₂]₄), tris(dimethylamino)silane (Si[N(CH₃)₂]₃H), bis(diethylamino)silane (Si[N(C₂H₅)₂]₂H₂), bis(tert-butylamino)silane (SiH₂[NH(C₄H₉)]₂), and (diisopropylamino)silane (SiH₃[N(C₃H₇)₂]) may also be used as the first precursor.

Further, a substance (gas) containing an alkoxy group and Si such as tetramethoxysilane (Si(OCH₃)₄) and tetraethoxysilane (Si(OC₂H₅)₄) may be used as the first precursor. Further, for example, a substance (gas) containing an alkoxy group, an amino group, and Si such as (dimethylamino)trimethoxysilane ((CH₃)₂NSi(OCH₃)₃) and (dimethylamino)triethoxysilane ((CH₃)₂N]Si(OC₂H₅)₃) may also be used as the first precursor. One or more of these may be used as the first precursor.

Further, for example, a substance (gas) containing a chloro group and Si such as bis(trichlorosilyl)methane ((SiCl₃)₂CH₂), 1,2-bis(trichlorosilyl)ethane ((SiCl₃)₂C₂H₄), 1,1,2,2-tetrachloro-1,2-dimethyldisilane ((CH₃)₂Si₂Cl₄), 1,2-dichloro-1,1,2,2-tetramethyldisilane ((CH₃)₄Si₂Cl₂), 1,1,3,3-tetrachloro-1,3-disilacyclobutane (C₂H₄Cl₄Si₂) may be used as the first precursor. These substances also contain an alkylene group or an alkyl group. Further, for example, a substance (gas) containing a chloro group and Si such as tetrachlorosilane (SiCl₄), hexachlorodisilane (Si₂Cl₆), and octachlorotrisilane (Si₃Cl₈) may be used as the first precursor. Further, for example, a substance (gas) containing a chloro group and Si such as hexachlorodisiloxane (Cl₃Si—O—SiCl₃) and octachlorotrisiloxane (Cl₃Si—O—SiCl₂—O—SiCl₃) may be used as the first precursor. These substances also contain oxygen. One or more of these may be used as the first precursor.

As the first catalyst, for example, an amine-based substance (amine-based gas) containing carbon (C), nitrogen (N), and hydrogen (H) may be used. A cyclic amine-based substance (cyclic amine-based gas) or a chain-shaped amine-based substance (chain-shaped amine-based gas) may be used as the amine-based substance. As the first catalyst, for example, a cyclic amine-based substance (cyclic amine-based gas) such as pyridine (C₅H₅N), aminopyridine (C₅H₆N₂), picoline (C₆H₇N), rutidine (C₇H₉N), pyrimidine (C₄H₄N₂), quinoline (C₉H₇N), piperazine (C₄H₁₀N₂), piperidine (C₅H₁₁N), pyrrolidine (C₄H₉N), and aniline (C₆H₇N) may be used. Further, for example, a chain-shaped amine-based substance (chain-shaped amine-based gas) such as triethylamine ((C₂H₅)₃N), diethylamine ((C₂H₅)₂NH), monoethylamine ((C₂H₅)NH₂), trimethylamine ((CH₃)₃N), dimethylamine ((CH₃)₂NH), and monomethylamine ((CH₃)NH₂) may be used as the first catalyst. One or more of these may be used as the first catalyst.

As the inert gas, for example, a noble gas such as nitrogen (N₂) gas, argon (Ar) gas, helium (He) gas, neon (Ne) gas, and xenon (Xe) gas may be used. One or more of these may be used as the inert gas. The same applies each step to be described later.

### {Step A2}

After Step A1 is completed, a first oxidizing agent and the first catalyst are supplied to the wafer 200.

Specifically, the valves 243c and 243b are opened to cause the first oxidizing agent and the first catalyst to flow through the gas supply pipes 232c and 232b, respectively. The first oxidizing agent and the first catalyst are regulated in flow rate by the MFCs 241c and 241b, respectively, and are supplied into the process chamber 201 via the nozzles 249c and 249b, respectively. The first oxidizing agent and the first catalyst are mixed inside the process chamber 201, and then are exhausted via the exhaust port 231a. At this time, the first oxidizing agent and the first catalyst are supplied to the wafer 200 from the lateral side of the wafer 200 (supply of first oxidizing agent+first catalyst). At this time, the valves 243e to 243g may be opened to supply an inert gas into the process chamber 201 via the nozzles 249a to 249c, respectively.

By supplying the first oxidizing agent and the first catalyst to the wafer 200 under a processing condition to be described later, it is possible to oxidize at least a portion of the first layer formed on the surface of the first base in Step A1. Thus, a second layer formed by oxidizing the first layer is formed on the surface of the first base.

A processing condition when the first oxidizing agent and the first catalyst are supplied in this step is exemplified as follows:
Processing temperature: room temperature (25 degrees C.) to 200 degrees C., specifically 25 to 150 degrees C.;
Processing pressure: 13 to 2666 Pa, specifically 13 to 1,333 Pa;
Processing time: 1 to 90 seconds, specifically 1 to 60 seconds;
Supply flow rate of first oxidizing agent: 0.001 to 2 slm, specifically 0.001 to 1 slm;
Supply flow rate of first catalyst: 0.001 to 2 slm, specifically 0.001 to 1 slm; and
Supply flow rate of inert gas (for each gas supply pipe): 0 to 20 slm.

After oxidizing the first layer formed on the surface of the first base to change (transform) the same into the second layer, the valves 243c and 243b are closed to stop the supply of the first oxidizing agent and the first catalyst into the process chamber 201, respectively. Then, a gaseous substance and the like remaining in the process chamber 201 are removed from the interior of the process chamber 201 by using the same processing sequence and processing condition as in the purging in Step A1 (purging). In addition, the processing temperature during the purging may be the same as the processing temperature during the supply of the first oxidizing agent and the first catalyst.

As the first oxidizing agent, for example, a substance containing oxygen (O) and hydrogen (H) (O- and H-containing gas) may be used. For example, an O- and H-containing substance (O- and H-containing gas) such as water vapor (H₂O), hydrogen peroxide (H₂O₂), hydrogen (H₂)+oxygen (O₂), and H₂ +ozone (O₃) may be used as the first oxidizing agent. In other words, O-containing substance +H-containing substance may be used as the O- and H-containing substance. In this case, instead of H₂, deuterium (D₂) may be used as the H-containing substance. One or more of these may be used as the first oxidizing agent.

In addition, notation of two substances such as “H₂+O₂” herein means a mixed substance (mixed gas) of H₂ and 0₂. When supplying the mixed substance (mixed gas), two substances may be mixed (pre-mixed) in a supply pipe and then may be supplied into the process chamber 201. Alternatively, the two substances may be separately supplied into the process chamber 201 from different supply pipes and then may be mixed (post-mixed) inside the process chamber 201.

As the first catalyst, for example, catalysts similar to the various first catalysts exemplified in Step A1 described above may be used.

### Predetermined Number of Repetitions

A cycle which includes Step A1 and Step A2 described above, specifically, a cycle which includes non-simultaneously (alternately) performing Step A1 and Step A2 is performed a predetermined number of times (m times, where m is an integer of 1 or 2 or more). Thus, as illustrated in FIG. 4B, a first film containing a first element and a second element may be selectively formed on the surface of the first base, among the surfaces of the first base and the second base of the wafer 200. For example, when the above-described first precursor, first oxidizing agent, and first catalyst are used, an oxide film such as a silicon oxide film (SiO film), a silicon oxycarbide film (SiOC film), or a silicon oxycarbonitride film (SiOCN film) may be selectively grown on the surface of the first base. In this manner, it is possible to selectively grow the first film, where, for example, the first element is silicon (Si) and the second element is oxygen (O), on the surface of the first base. The first film may also contain carbon (C) or nitrogen (N).

Further, the above-described cycle may be performed multiple times. In other words, a thickness of the second layer formed per cycle may be set to be thinner than a desired thickness of the first film and the above-described cycle may be performed multiple times until the thickness of the first film formed by stacking the second layer reaches the desired thickness.

In addition, when performing Step A1 and Step A2, there is a case where formation or growth of the first film occurs very minimally on the surface of the second base. However, in this case as well, the thickness of the first film formed on the surface of the second base is significantly thinner than the thickness of the first film formed on the surface of the first base. Herein, the expression “selectively (preferentially) forming the first film on the surface of the first base” includes a case where the first film is formed on the surface of the first base without being formed on the surface of the second base, and a case where a very thin first film is formed on the surface of the second base while a first film much thicker than the first film formed on the surface of the second base is formed on the surface of the first base.

In this step, the thickness of the first film formed on the surface of the first base may be 0.5 nm or more and 10 nm or less, specifically 1 nm or more and 5 nm or less, and more specifically 1.5 nm or more and 3 nm or less.

In a case where the thickness of the first film is less than 0.5 nm, an amount of at least a portion of molecular structures of molecules (residues derived from the modifying agent) constituting the modifying agent adsorbed on the surface of the first film may be insufficient in Step B to be described later. In this case, an adsorption inhibition effect by an inhibitor layer formed on the surface of the first film may become insufficient. Such an issue may be resolved by setting the thickness of the first film to be 0.5 nm or more. The issue may be effectively resolved by making the thickness of the first film at 1 nm or more. The issue may be more effectively resolved by making the thickness of the first film at 1.5 nm or more.

In a case where the thickness of the first film is thicker than 10 nm, an adsorption inhibition effect on at least a portion of H terminations on the surface of the second base may be invalidated by an action of the first film-forming agent, resulting in an insufficient adsorption inhibition effect by the H terminations. Thus, the first film may also be formed on the surface of the second base, and an inhibitor layer may also be formed on the surface of the second base in the subsequent Step B. Such an issue may be resolved by setting the thickness of the first film to be 10 nm or less. The issue may be effectively resolved by setting the thickness of the first film to be 5 nm or less. The issue may be more effectively resolved by setting the thickness of the first film to be 3 nm or less.

The thickness of the first film formed in this step may be the same as or different from a thickness of a second film formed in Step C to be described later. In addition, in this step, specifically, the thickness of the first film may be less than or equal to the thickness of the second film formed in Step C to be described later, and more specifically, the thickness of the first film may be less than the thickness of the second film formed in Step C. In other words, in this step, specifically, the thickness of the first film may be different from the thickness of the second film formed in Step C, and more specifically, the thickness of the first film may be less than the thickness of the second film. Thus, it is possible to increase a difference in film thickness between the first film formed on the surface of the first base and the second film formed on the surface of the second base (i.e., thickness of the second film-thickness of the first film), thereby enhancing a selectivity. Further, a ratio of the thickness of the second film formed on the surface of the second base to the thickness of the first film formed on the surface of the first base may be increased to enhance the selectivity.

Further, in a case where the first film is too thick, in this step, it may lead to desorption of H terminations from the surface of the second base or substitutions of H terminations with other terminations. This may result in formation of an inhibitor layer on the surface of the first film and the surface of the second base in Step B, which may hinder the growth of the second film on the surface of the second base in Step C. In this regard, the thickness of the first film formed in this step may be set to be less than the thickness of the second film formed in Step C.

Further, in this step, by setting a film formation condition for the first film to be a condition where a reaction occurs gently, that is, a condition with low reactivity or reaction intensity, H terminations may remain on the surface of the second base. In this step, in a case where the film formation condition for the first film is set to be a condition with high reactivity or reaction intensity, it may lead to desorption of H terminations from the surface of the second base or substitutions of H terminations with other terminations. This may result in formation of an inhibitor layer on the surface of the first film and on the surface of the second base in Step B, which may hinder the growth of the second film on the surface of the second base in Step C. In this regard, in this step, the film formation condition for the first film may be set to be a condition where a reaction occurs gently.

Specifically, for example, by performing this step under at least one of the following processing conditions, it is possible to set the film formation condition in this step may to be a condition where a reaction occurs gently, thereby allowing H terminations to remain on the surface of the second base. Further, by adopting at least one of the following processing conditions, this step is performed under a processing condition with a lower film formation rate than Step C to be described later.

A processing temperature in Step A (Step A1 and Step A2) is set to be higher than a processing temperature in Step C (Step C1 and Step C2).

A processing pressure in Step A (Step A1 and Step A2) is set to be lower than a processing pressure in Step C (Step C1 and Step C2).

A supply flow rate of first precursor in Step A1 is set to be smaller than a supply flow rate of second precursor in Step C1.

A supply flow rate of first oxidizing agent in Step A2 is set to be smaller than a supply flow rate of second oxidizing agent in Step C2.

A supply time of first precursor in Step A1 is set to be shorter than a supply time of second precursor in Step C1.

A supply time of first oxidizing agent in Step A2 is set to be shorter than a supply time of second oxidizing agent in Step C2.

### Step B

Thereafter, an inhibitor layer is formed on the first film through adsorption of at least a portion of molecular structures of molecules constituting a modifying agent on a surface of the first film formed on the surface of the first base by supplying the modifying agent to the wafer 200.

Specifically, the valve 243d is opened to cause the modifying agent to flow through the gas supply pipe 232d. The modifying agent is regulated in flow rate by the MFC 241d, is supplied into the process chamber 201 via the nozzle 249a, and is exhausted via the exhaust port 231a. At this time, the modifying agent is supplied to the wafer 200 from the lateral side of the wafer 200 (supply of modifying agent). At this time, the valves 243e to 243g may be opened to supply an inert gas into the process chamber 201 through the nozzles 249a to 249c respectively.

By supplying the modifying agent to the wafer 200 under a processing condition to be described later, it is possible to cause at least a portion of molecular structures of molecules constituting the modifying agent to be selectively (preferentially) adsorbed on the surface of the first film among the surfaces of the first film and the second base. Thus, as illustrated in FIG. 4C, an inhibitor layer is selectively formed on the surface of the first film formed on the surface of the first base. In other words, in this step, it is possible to modify the surface of the first film by supplying the modifying agent to the wafer 200 such that at least a portion of molecular structures of molecules constituting the modifying agent is selectively adsorbed on the surface of the first film to form the inhibitor layer.

In this step, a property that an incubation time on the surface of the second base is longer than an incubation time on the surface of the first film when the inhibitor layer is formed by using the modifying agent is used to selectively form the inhibitor layer on the surface of the first film. As described above, in Step A, an oxide film such as a SiO film, SiOC film, or SiOCN film is formed as the first film on the surface of the first base. A surface of this oxide film contains OH terminations, and a surface of a Si film, which is the second base, contains H terminations. When the inhibitor layer is formed, the incubation time on the H terminations on the surface of the Si film is longer than the incubation time on the OH terminations on the surface of the oxide film. In other words, it is more difficult to form the inhibitor layer on the surface of the Si film, which contains H terminations, than on the surface of the oxide film, which contains OH terminations. Therefore, in this step, it is possible to selectively (preferentially) form the inhibitor layer on the surface of the oxide film, which is the first film, rather than on the surface of the Si film, which is the second base. In addition, in this regard, it may be said that when attempting to form the inhibitor layer on a surface containing OH terminations or H terminations, the H terminations or the surface containing the H terminations may cause a film formation inhibition effect (an adsorption inhibition effect or a reaction inhibition effect).

The inhibitor layer formed in this step contains at least a portion of molecular structures of molecules constituting the modifying agent, which is a residue derived from the modifying agent. The inhibitor layer prevents adsorption of a second film-forming agent (second precursor) on the surface of the first film in Step C to be described later, thereby inhibiting (preventing) progress of a film formation reaction on the surface of the first film. In this regard, the inhibitor layer is also referred to as a film formation inhibition layer (an adsorption inhibition layer or a reaction inhibition layer).

As at least a portion of molecular structures of molecules constituting the modifying agent, for example, a trialkylsilyl group such as a trimethylsilyl group (—SiMe₃), a triethylsilyl group (—SiEt₃), or the like may be exemplified. In these cases, the surface of the first film is terminated by an alkyl group such as a methyl group or ethyl group. The alkyl group (alkylsilyl group) such as a methyl group (trimethylsilyl group) or ethyl group (triethylsilyl group), which terminates the surface of the first film, constitutes the inhibitor layer, which may prevent adsorption of a second film-forming agent (second precursor) on the surface of the first film in Step C to be described later, thereby inhibiting (preventing) progress of a film formation reaction on the surface of the first film.

In addition, the term “inhibitor” as used herein may refer to the modifying agent or a residue derived from the modifying agent, for example, at least a portion of molecular structures of molecules constituting the modifying agent, as well as a film formation inhibition effect (an adsorption inhibition effect or a reaction inhibition effect), and may also be used as a collective term for the entirety of these.

A processing condition when the modifying agent is supplied in this step is exemplified as follows:
Processing temperature: room temperature (25 degrees C.) to 500 degrees C., specifically, 25 to 250 degrees C.;
Processing pressure: 5 to 2000 Pa, specifically, 10 to 1000 Pa;
Processing time: 1 second to 120 minutes, specifically 30 seconds to 60 minutes;
Supply flow rate of modifying agent: 0.001 to 3 slm, specifically 0.001 to 0.5 slm; and
Supply flow rate of inert gas (for each gas supply pipe): 0 to 20 slm.

After the inhibitor layer is formed on the surface of the first film, the valve 243d is closed to stop the supply of the modifying agent into the process chamber 201. Then, a residual gaseous substance and the like in the process chamber 201 are excluded from the interior of the process chamber 201 under the same processing sequence and processing condition as in the purging in Step A1 (purging). In addition, the processing temperature during the purging may be the same as the processing temperature during the supply of the modifying agent.

As the modifying agent, for example, (dimethylamino)trimethylsilane ((CH₃)₂NSi(CH₃)₃), (diethylamino)triethylsilane ((C₂H₅)₂NSi(C₂H₅)₃), (dimethylamino)triethylsilane ((CH₃)₂NSi(C₂H₅)₃), (diethylamino)trimethylsilane ((C₂H₅)₂NSi(CH₃)₃), (dipropylamino)trimethylsilane ((C₃H₇)₂NSi(CH₃)₃), (dibutylamino)trimethylsilane ((C₄H₉)₂NSi(CH₃)₃), (trimethylsilyl)amine ((CH₃)₃SiNH₂), (triethylsilyl)amine ((C₂H₅)₃SiNH₂), (dimethylamino)silane ((CH₃)₂NSiH₃), (diethylamino)silane ((C₂H₅)₂NSiH₃), (dipropylamino)silane ((C₃H₇)₂NSiH₃), (dibutylamino)silane ((C₄H₉)₂NSiH₃) or the like may be used. One or more of these may be used as the modifying agent.

Further, for example, bis(dimethylamino)dimethylsilane ([(CH₃)₂N]₂Si(CH₃)₂), bis(diethylamino)diethylsilane ([(C₂H₅)₂N]₂Si(C₂H₅)₂), bis(dimethylamino)diethylsilane ([(CH₃)₂N]₂Si(C₂H₅)₂), bis(diethylamino)dimethylsilane ([(C₂H₅)₂N]₂Si(CH₃)₂), bis(dimethylamino))silane ([(CH₃)₂N]₂SiH₂), bis(diethylamino)silane ([(C₂H₅)₂N]₂SiH₂), bis(dimethylaminodimethylsilyl)ethane ([(CH₃)₂N(CH₃)₂Si]₂C₂H₆), bis(dipropylamino)silane ([(C₃H₇)₂N]₂SiH₂), bis(dibutylamino)silane ([(C₄H₉)₂N]₂SiH₂), bis(dipropylamino)dimethylsilane ([(C₃H₇)₂N]₂Si(CH₃)₂), bis(dipropylamino)diethylsilane ([(C₃H₇)₂N]₂Si(C₂H₅)₂), (dimethylsilyl)diamine ((CH₃)₂Si(NH₂)₂), (diethylsilyl)diamine ((C₂H₅)₂Si(NH₂)₂), (dipropylsilyl)diamine ((C₃H₇)₂Si(NH₂)₂), bis(dimethylaminodimethylsilyl)methane ([(CH₃)₂N(CH₃)₂Si]₂CH₂), bis(dimethylamino)tetramethyldisilane ([(CH₃)₂N]₂(CH₃)₄Si₂) or the like may also be used as the modifying agent. One or more of these may be used as the modifying agent.

In addition at least a portion of molecular structures of molecules constituting the modifying agent may be adsorbed on a portion of the surface of the second base when performing this step. However, even in this case, an amount of such an adsorption is small, and an amount of adsorption on the surface of the first film is overwhelmingly large. Herein, ““at least a portion of molecular structures of molecules constituting the modifying agent are selectively (preferentially) adsorbed on the surface of the first film” includes a case where even at least a portion of molecular structures of molecules constituting the modifying agent is not adsorbed on the surface of the second base, while at least a portion of molecular structures of molecules constituting the modifying agent is adsorbed on the surface of the first film, and a case where a very small amount of at least a portion of molecular structures of molecules constituting the modifying agent is adsorbed on the surface of the second base, while a much greater amount of at least a portion of molecular structures of molecules constituting the modifying agent is adsorbed on the surface of the first film than the surface of the second base.

### Step C

Thereafter, by supplying a second film-forming agent to the wafer 200 with the inhibitor layer formed on the surface of the first film, a second film containing the first element and the second element is formed on the surface of the second base, as illustrated in FIG. 4D. In this step, specifically, the following Steps C1 and C2 are sequentially executed.

### {Step C1}

In this step, a second precursor and a second catalyst are supplied to the wafer 200. A processing sequence at this time may be the same as the processing sequence in Step A1.

By supplying the second precursor and the second catalyst to the wafer 200 under a processing condition to be described later, at least a portion of molecular structure of molecules constituting the second precursor may be selectively (preferentially) chemisorbed on the surface of the second base among the surfaces of the inhibitor layer and the second base. This allows a third layer to be selectively formed on the surface of the second base. The third layer contains at least a portion of molecular structures of molecules constituting the second precursor, which is a residue derived from the second precursor.

In this step, a property that an incubation time on the surface of the inhibitor layer is longer than an incubation time on the surface of the second base when forming the third layer by using the second precursor, which is a second film-forming agent, is used to selectively form the third layer on the surface of the second base. As described above, the surface of the Si film, which is the second base, contains H terminations, and the surface of the inhibitor layer contains alkyl group terminations. When the third layer is formed, an incubation time on the alkyl group terminations in the surface of the inhibitor layer is longer than an incubation time on the H terminations on the surface of the Si film. In other words, it is more difficult to form the third layer on the surface of the inhibitor layer, which contains alkyl group terminations, than on the surface of the Si film, which contains H terminations. Therefore, in this step, it is possible to selectively (preferentially) form the third layer on the surface of the Si film, which is the second base, rather than on the surface of the inhibitor layer. In addition, in this regard, it may be said that when attempting to form the third layer on a surface containing H terminations or alkyl group terminations, the alkyl group terminations or the surface containing the alkyl group terminations may cause a film formation inhibition effect (an adsorption inhibition effect or a reaction inhibition effect).

A processing condition when the second precursor and the second catalyst are supplied in this step is exemplified as follows:
Processing temperature: room temperature (25 degrees C.) to 200 degrees C., specifically, 25 to 150 degrees C.;
Processing pressure: 133 to 4,000 Pa, specifically, 133 to 2,666 Pa;
Processing time: 1 to 120 seconds, specifically, 1 to 90 seconds;
Supply flow rate of second precursor: 0.001 to 3 slm, specifically, 0.01 to 2 slm;
Supply flow rate of second catalyst: 0.001 to 3 slm, specifically, 0.01 to 2 slm; and
Supply flow rate of inert gas (for each gas supply pipe): 0 to 20 slm.

After the third layer is formed on the surface of the second base, the supply of the second precursor and the second catalyst into the process chamber 201 is stopped. Then, a residual gaseous substance and the like in the process chamber 201 are removed from the interior of the process chamber 201 under the same processing sequence and processing condition as in the purging in Step A1 (purging). In addition, the processing temperature during the purging may be the same as the processing temperature during the supply of the second precursor and the second catalyst.

As the second precursor, for example, precursors similar to the various first precursors exemplified in Step A1 described above may be used. Although the second precursor may be the same as or different from the first precursor used in Step A1, specifically, the second precursor may be the same as the first precursor.

As the second catalyst, for example, catalysts similar to the various first catalysts exemplified in Step A1 described above may be used. Although the second catalyst may be the same as or different from the first catalyst used in Step A1, specifically, the second catalyst may be the same as the first catalyst.

### {Step C2}

After Step C1 is completed, a second oxidizing agent and the second catalyst are supplied to the wafer 200. The processing sequence at this time may be the same as the processing sequence in Step A2.

By supplying the second oxidizing agent and the second catalyst to the wafer 200 under a processing condition to be described later, it is possible to oxidize at least a portion of the third layer formed on the surface of the second base in Step C1. Thus, a fourth layer formed by oxidizing the third layer is formed on the surface of the second base.

A processing condition when the second oxidizing agent and the second catalyst are supplied in this step is exemplified as follows:
Processing temperature: room temperature (25 degrees C.) to 200 degrees C., specifically 25 to 150 degrees C.;
Processing pressure: 133 to 4,000 Pa, specifically, 133 to 2,666 Pa;
Processing time: 1 to 120 seconds, specifically, 1 to 90 seconds;
Supply flow rate of second oxidizing agent: 0.001 to 3 slm, specifically, 0.01 to 2 slm;
Supply flow rate of second catalyst: 0.001 to 3 slm, specifically, 0.01 to 2 slm; and
Supply flow rate of inert gas (for each gas supply pipe): 0 to 20 slm.

After the fourth layer is formed on the surface of the second base, the supply of the second oxidizing agent and the second catalyst into the process chamber 201 is stopped. Then, a residual gaseous substance and the like in the process chamber 201 are removed from the interior of the process chamber 201 under the same processing sequence and processing condition as in the purging in Step A1 (purging). In addition, the processing temperature during the purging may be the same as the processing temperature during the supply of the second oxidizing agent and the second catalyst.

As the second oxidizing agent, for example, oxidizing agents similar to the various first oxidizing agents exemplified in Step A2 described above may be used. Although the second oxidizing agent may be the same as or different from the first oxidizing agent used in Step A2, specifically, the second oxidizing agent may be the same as the first oxidizing agent.

As the second catalyst, for example, catalysts similar to the various first catalysts exemplified in Step A1 described above may be used. Although the second catalyst may be the same as or different from the first catalyst used in Step A1, specifically, the second catalyst may be the same as the first catalyst.

### Performing Predetermined Number of Times

A cycle which includes Step C1 and Step C2 described above, specifically, a cycle which includes non-simultaneously (alternately) performing Step C1 and Step C2 is performed a predetermined number of times (n times, where n is an integer of 1 or 2 or more). Thus, as illustrated in FIG. 4D, a second film containing the first element and the second element may be selectively formed on the surface of the second base, among the surfaces of the first base and the second base of the wafer 200. For example, when the above-described second precursor, second oxidizing agent, and second catalyst are used, an oxide film such as a SiO film, SiOC film, or SiOCN film may be selectively grown on the surface of the second base. In this manner, it is possible to selectively grow the second film, where, for example, the first element is Si and the second element is O, on the surface of the second base. The first film may also contain C or N.

In addition, both the first film and the second film contain the first element and the second element. The second film may be made of the same material as the first film. For example, in a case of the above-described example, both the first film and the second film may be SiO films, SiOC films, or SiOCN films. In addition, the second film may be the same in composition ratio (constituent element ratio) as the first film. Further, the second film may be made of a different material from the first film. For example, in a case of the above-mentioned example, the first film may be a SiO film and the second film may be a SiOC film, or the first film may be a SiO film and the second film may be a SiOCN film.

Further, the above-described cycle may be performed multiple times. In other words, a thickness of the fourth layer formed per cycle may be set to be less than a desired thickness of the second film and the above-described cycle may be performed multiple times until the thickness of the second film formed by stacking the fourth layer reaches the desired thickness.

In addition, when Step C1 and Step C2 are performed, formation or growth of the second film may occur very minimally on the surface of the inhibitor layer. However, even in this case, the thickness of the second film formed on the surface of the inhibitor layer is much less than the thickness of the second film formed on the surface of the second base. Herein, “selectively (preferentially) forming the second film on the surface of the second base” includes a case where the second film is not formed on the surface of the inhibitor layer and is formed on the surface of the second base, and a case where a very thin second film is formed on the surface of the inhibitor layer while a second film much thicker than the second film formed on the surface of the inhibitor layer is formed on the surface of the second base.

In this step, it is desirable to increase the thickness of the second film formed on the surface of the second base, thereby enhancing a selectivity. The thickness of the second film may be, for example, 0.5 nm or more and 15 nm or less. In addition, the second film formed in this step may be etched in the same manner as the first film in Step D to be described later. Therefore, the thickness of the second film in this step may be increased considering an amount of the second film to be etched in Step D.

### Step D

Thereafter, the first film is removed by supplying an etching agent to the wafer 200 after the second film is formed on the surface of the second base.

Specifically, the valve 243h is opened to cause the etching agent to flow through the gas supply pipe 232h. The etching agent is regulated in flow rate by the MFC 241h, is supplied into the process chamber 201 via the nozzle 249a, and is exhausted via the exhaust port 231a. At this time, the etching agent is supplied to the wafer 200 from the lateral side of the wafer 200 (supply of etching agent). At this time, the valves 243e to 243g may be opened to supply an inert gas into the process chamber 201 via the nozzles 249a to 249c respectively.

By supplying the etching agent to the wafer 200 under a processing condition to be described later, the first film formed on the surface of the first base may be removed (etched) to expose the surface of the first base. In addition, when the first film is removed, the inhibitor layer remaining on the surface of the first film is also removed. Thus, the surface of the first base of the wafer 200 is exposed as illustrated in FIG. 4E.

A processing condition during the supply of the etching agent in this step is exemplified as follows:
Processing temperature: room temperature (25 degrees C.) to 400 degrees C., specifically, 50 to 200 degrees C.;
Processing pressure: 1 to 13,332 Pa, specifically, 100 to 1,333 Pa;
Processing time: 0.1 to 60 minutes, specifically, 1 to 30 minutes;
Supply flow rate of etching agent: 0.05 to 5 slm, specifically, 0.1 to 2 slm; and
Supply flow rate of inert gas (for each gas supply pipe): 1 to 10 slm, specifically, 2 to 10 slm.

After the first film on the surface of the first base is removed, the valve 243h is closed to stop the supply of the etching agent into the process chamber 201. Then, a residual gaseous substance and the like in the process chamber 201 are removed from the interior of the process chamber 201 under the same processing sequence and processing condition as in the purging in Step A1 (purging). In addition, the processing temperature during the purging may be the same as the processing temperature during the supply of the etching agent.

As the etching agent, for example, a fluorine (F)-containing substance (F-containing gas) may be used. For example, a F-containing substance (F-containing gas) such as chlorine trifluoride (ClF₃), chlorine fluoride (ClF), nitrogen fluoride (NF₃), fluorine (F₂), hydrogen fluoride (HF), and aqueous HF solution (DHF) may be used as the etching agent. One or more of these may be used as the etching agent.

### After-Purge and Returning to Atmospheric Pressure

After Step D is completed, an inert gas serving as a purge gas is supplied into the process chamber 201 from each of the nozzles 249a to 249c, and is exhausted via the exhaust port 231a. Thus, the interior of the process chamber 201 is purged, and any gases, reaction by-products, and the like remaining in the process chamber 201 are removed from the interior of the process chamber 201 (after-purge). Thereafter, the internal atmosphere of the process chamber 201 is replaced with the inert gas (inert gas replacement), and the internal pressure of the process chamber 201 is returned to the atmospheric pressure (returning to atmospheric pressure).

### Boat Unloading and Wafer Discharging

Thereafter, the seal cap 219 is lowered by the boat elevator 115 to open the lower end of the manifold 209. Then, the processed wafers 200 supported by the boat 217 are unloaded from the lower end of the manifold 209 to the outside of the reaction tube 203 (boat unloading). After the boat is unloaded, the shutter 219s is moved, and the lower end opening of the manifold 209 is sealed by the shutter 219s via the O-ring 220c (shutter closing). The processed wafers 200 are unloaded to the outside of the reaction tube 203 and are then discharged from the boat 217 (wafer discharging).

### (3) Effects of Embodiments of the Present Disclosure

According to the embodiments of the present disclosure, one or more of the following effects are obtained.

By performing Step A, Step B, and Step C, it is possible to selectively form the second film on the surface of the second base with high precision. This is because the incubation time on the surface of the second base is longer than the incubation time on each of the surfaces of the first base and the first film, and because the incubation time on the surface of the inhibitor layer is longer than the incubation time on the surface of the second base. In other words, this is because the incubation time is the longest on the surface of the inhibitor layer, the second longest on the surface of the second base, and the shortest on each of the surfaces of the first base and the first film. In this manner, by controlling the balance of the incubation time on the respective surfaces, it is possible to selectively form the first film on the surface of the first base in Step A, to selectively form the inhibitor layer on the surface of the first film in Step B, and to selectively form the second film on the surface of the second base in Step C with high precision. In other words, according to the embodiments of the present disclosure, it is possible to selectively form a desired film on a desired surface with high precision.

By performing Step A, Step B, and Step C, a first film containing a first element and a second element is formed on the surface of a first base, an inhibitor layer is formed on the surface of the first film, and a second film containing the first element and the second element is formed on the surface of a second base. For example, in a case where the first film contains a first element and a second element and the second film contains a third element and a fourth element, there is a possibility that the third element or the fourth element may be mixed into the first film, or the first element or the second element may be mixed into the second film, that is, there is a possibility that cross-contamination may occur, leading to deterioration in film characteristics. In contrast, when the first and second films each contain the same element, i.e., the first element and the second element, the above-described cross-contamination may be prevented and the film characteristics may be improved. In particular, this effect becomes noticeable when the first film and the second film are formed in the same process chamber (in-situ).

Further, when the first and second films each contain the first element and the second element and an etch-back is performed on the first film by using an etching agent after the formation of the second film, i.e., when performing Step D after Step C, it is possible to control the film thickness of the second film, which may be exposed to the etching agent along with the first film, with high controllability. Further, when the first and second films each contain the first element and the second element, a supply system of a first film-forming agent to form the first film and a supply system of a second film-forming agent to form the second film may be shared, resulting in a simplified supply system. This significantly reduces an apparatus cost and simplifies an apparatus maintenance. Further, when the first and second films each contain the first element and the second element, a film formation temperature of the first film and a film formation temperature of the second film may be made equal to each other. This may improve a throughout when repeating the processing of Step A, Step B, and Step C on different wafers 200, i.e., when performing continuous processing on different wafers 200, thereby improving a productivity in continuous processing.

Further, specifically, the first film and the second film may be oxide films, more specifically, the first element may be Si and the second element may be O, and even more specifically, the first film may be a SiO film, SiOC film, or SiOCN film and the second film may be a SiO film, SiOC film, or SiOCN film. This enables the above-described effects to be effectively realized. In addition, materials (molecular structure, constituent elements) of both the first film and the second film may be the same, such as a case where both the first film and the second film are SiO films. In this case, when performing Step D after Step C, the second film is etched in the same manner as the first film, such that the film thickness of the second film may be controlled with higher controllability. Further, materials of both the first film and the second film may be different, such as a case where both the first film is a SiO film and the second film is a SiOC film or SiOCN film. In this case, when the first film is a SiO film and the second film is a SiOC film or SiOCN film, and Step D is performed after performing Step C, the etching of the second film may be prevented due to an effect of the second film containing C or N, allowing a selective etching of the first film. Thus, it is possible to control the film thickness of the second film, which may be exposed to the etching agent along with the first film during the etching of the first film, with higher controllability.

Specifically, as a first film-forming agent, a first precursor and a first oxidizing agent may be supplied to the wafer 200 in Step A and, as a second film-forming agent, a second precursor and a second oxidizing agent may be supplied to the wafer 200 in Step C. Specifically, in Step A, a cycle which includes Step A1 of supplying the first precursor to the wafer 200 and Step A2 of supplying the first oxidizing agent to the wafer 200 may be performed a predetermined number of times, and in Step C, a cycle which includes Step C1 of supplying the second precursor to the wafer 200 and Step C2 of supplying the second oxidizing agent to the wafer 200 may be performed a predetermined number of times. Further, a first catalyst may be supplied in at least one selected from the group of Step A1 and Step A2, and a second catalyst may be supplied in at least one selected from the group of Step C1 and Step C2. This enables the above-described effects to be effectively realized. Further, an action of each catalyst may cause a processing temperature in each step to be lowered, thus causing a reaction occurring in each step to be milder, which may also improve the selectivity in the selective growth of the first and second films.

Specifically, the first precursor and the second precursor may be substances containing at least one selected from the group of an amino group, an alkoxy group, and a chloro group, while the first oxidizing agent and the second oxidizing agent may be substances containing O and H. Further, the first precursor and the second precursor may be the same substance or different substances. Further, the first oxidizing agent and the second oxidizing agent may be the same substance or different substances. Further, more specifically, the first precursor and the second precursor may be the same substance and that the first oxidizing agent and the second oxidizing agent may be the same substance. Further, more specifically, when the first catalyst and the second catalyst are used, the first precursor and the second precursor may be the same substance, the first oxidizing agent and the second oxidizing agent may be the same substance, and the first catalyst and the second catalyst may be the same substance. These may also be referred to as cases where the first film-forming agent and the second film-forming agent are the same substance. This enables the above-described effects to be effectively realized.

Specifically, the thickness of the first film may be set to be less than or equal to the thickness of the second film, or the thickness of the first film may be less than the thickness of the second film. Further, specifically, Step A may be performed under a processing condition with a lower film formation rate than Step C. This allows a reaction during the formation of the first film to be milder than a reaction during the formation of the second film. Thus, a ratio of the thickness of the second film formed on the surface of the second base to the thickness of the first film formed on the surface of the first base may be increased, thereby enhancing the selectivity.

Specifically, the temperature of the wafer 200 may be the same during Step A, Step B, and Step C. In other words, specifically, the processing temperature may be the same in Step A, Step B, and Step C. This enables the above-described effect relating to the productivity to be effectively realized.

Further, specifically, Step A, Step B, and Step C may be performed within the same space. In other words, as described above, Step A, Step B, and Step C may be performed in the same process chamber (in-situ). Thus, it is possible to continuously perform Step A, Step B, and Step C without transferring the wafer 200 among these steps. This makes it possible to improve a throughput, leading to an improved productivity. Further, by performing Step A, Step B, and Step C within the same space (in the same process chamber), it is possible to prevent the wafer 200 from being exposed to the atmosphere among these steps, thereby avoiding issues such as deterioration in selectivity due to atmosphere exposure. This ensures proper selective growth. Further, in addition to Step A, Step B, and Step C, Step D may be performed within the same space (within the same process chamber) as Step A, Step B, and Step C, as described above.

### (4) Modifications

The processing sequence in the embodiments of the present disclosure may be changed as in the following modifications. These modifications may be combined arbitrarily. Unless otherwise specified, a processing sequence and a processing condition for each step in each modification may be the same as the processing sequence and the processing condition for each step in the above-described processing sequence.

### First Modification

In a case where the first film formed on the surface of the first base may not be removed, Step D may be omitted as illustrated in the processing sequence below. In this modification as well, effects similar to those in the above-described embodiments are obtained.

(First Precursor+First Catalyst→First Oxidizing Agent+First Catalyst)×m→Modifying Agent→(Second Precursor+Second Catalyst→Second Oxidizing Agent+Second Catalyst)×n

### Second Modification

(e) Step E of forming a third film on the second film may also be performed by supplying a third film-forming agent to the wafer 200 after the formation of the second film. Specifically, Step E may be performed after Step C and before Step D. In the following example, a case where in Step E, a third precursor, a third oxidizing agent, and a third catalyst are supplied as the third film-forming agent to the wafer 200 will be described. In this case, specifically, in Step E, a cycle which includes (e1) supplying a third precursor and a third catalyst to the wafer 200 (Step E1) and (e2) supplying a third oxidizing agent and the third catalyst to the wafer 200 (Step E2) may be performed a predetermined number of times (p times, where p is an integer of 1 or 2 or more), as illustrated in the processing sequence below. In addition, the supply of the third catalyst may be omitted in at least one selected from the group of Step E1 and Step E2.

(First Precursor+First Catalyst→First Oxidizing Agent+First Catalyst)×m→Modifying Agent→(Second Precursor+Second Catalyst→Second Oxidizing Agent+Second Catalyst)×n→(Third Precursor+Third Catalyst→Third Oxidizing Agent+Third Catalyst)×p→Etching Agent (Etch-Back)

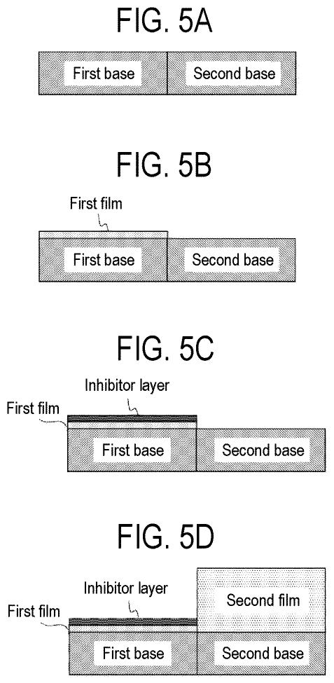

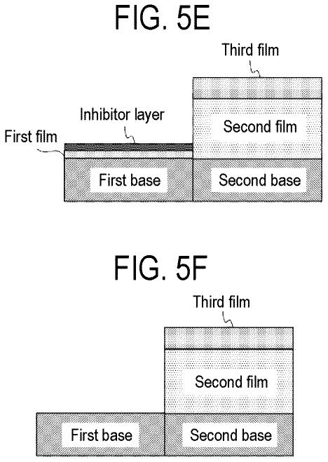

This modification will be described mainly with reference to FIGS. 5A to 5F. First, similar to the above-described embodiments, the wafer 200 including a first base and a second base on a surface thereof is used, as illustrated in FIG. 5A. Step A is performed by using this wafer 200 to selectively form a first film on a surface of the first base, as illustrated in FIG. 5B. Thereafter, Step B is performed to form an inhibitor layer on a surface of the first film, as illustrated in FIG. 5C. Thereafter, Step C is performed to selectively form a second film on a surface of the second base, as illustrated in FIG. 5D. Subsequently, Step E is performed to selectively form a third film on a surface of the second film, as illustrated in FIG. 5E. Thereafter, Step D is performed to remove the first film formed on the surface of the first base along with the inhibitor layer, as illustrated in FIG. 5F. In this way, a stacked film constituted by the second film and the third film selectively stacked on the surface of the second base among the surfaces of the first and second bases of the wafer 200 is formed.

A processing sequence and a processing condition for Step E in this modification may be the same as the processing sequence and the processing condition for Step C in the above-described processing sequence, except for using the third film-forming agent (third precursor, third oxidizing agent, and third catalyst) and supplying the third film-forming agent to the wafer 200 after Step C. As the third precursor, for example, precursors similar to the various first precursors exemplified in Step A1 described above may be used. As the third oxidizing agent, for example, oxidizing agents similar to the various first oxidizing agents exemplified in Step A2 described above may be used. As the third catalyst, catalysts similar to the various first catalysts exemplified in Step A1 described above may be used. Further, specifically, the third film-forming agent (third precursor, third oxidizing agent, and third catalyst) may differ from the second film-forming agent (second precursor, second oxidizing agent, and second catalyst). Further, specifically, the third film may be made of a different material from the second film. Further, the third film may be made of a different material from the first film. For example, in a case where the first film is a SiO film and the second film is a SiO film, the third film may be a SiOC film or a SiOCN film. Further, for example, in a case where the first film is a SiO film and the second film is a SiOC film, the third film may be a SiOC film or a SiOCN film.

Even in this modification, the same effects as in the above-described embodiments are obtained. Further, in this modification, by forming the third film on the second film, the third film may act as an etching block film (cap film, etching barrier film, etching inhibitor film) when etching back the first film by using an etching agent after the formation of the second film. Therefore, specifically, the third film may be higher in etching resistance than the second film. Further, specifically, the third film may be higher in etching resistance than the first film. For example, when the third film is a film containing C or N, such as a SiOC film or SiOCN film, an etching resistance of the third film may be enhanced. This allows the selective etching of the first film without etching the second film, enabling the thickness of the second film to be controlled with high controllability even when etching back the first film.

### Other Embodiments of Present Disclosure

The embodiments of the present disclosure are specifically described above. However, the present disclosure is not limited to the above-described embodiments and may be changed in various ways without departing from the gist of the present disclosure.

For example, the wafer 200 may include multiple types of regions made of different materials serving as the first base, and may include multiple types of regions made of different materials serving as the second base. In the wafer 200, any base that includes a surface (terminations) with a shorter incubation time during the formation of the first film than the second base may be used as the first base. That is, any base may be used as the first base and the second base in the wafer 200 as long as the base includes at least two types of surfaces with different incubation times during the formation of the first film. For example, specifically, the first base may include an insulating film, the second base may include at least one selected from the group of a semiconductor substrate, a film composed of a semiconductor element, and a film composed of a metal element. Further, specifically, the insulating film may include at least one selected from the group of a semiconductor insulating film and a metal insulating film. In these cases, it is possible to appropriately generate the above-described difference in incubation time on the respective surfaces of the first base and the second base during the formation of the first film. In the embodiments of the present disclosure as well, effects similar to those in the above-described embodiments are obtained.

The first base may be a semiconductor insulating film such as a SiO film (including a native oxide film), a SiOC film, a SiOCN film, a silicon oxynitride film (SiON film), a silicon carbide film (SiC film), a silicon carbonitride film (SiCN film), silicon boron nitride film (SiBN film), silicon boron carbonitride film (SiBCN film), and other Si-based insulating films, in addition to the SiN film described above, or may be a metal insulating film such as a hafnium oxide film (HfO film), a zirconium oxide film (ZrO film), an aluminum oxide film (AlO film), and other metal-based oxide film. At least one of these films may be used as the first base.

The second base may be a semiconductor substrate such as a Si wafer (single crystal Si), in addition to the Si film described above. In addition, the Si film includes a film composed of a semiconductor element such as an amorphous silicon film (a-Si film), polysilicon film (poly-Si film), a mixed crystal film of an amorphous silicon and a polysilicon, and an epitaxial silicon film (Epi-Si film). Further, the second base may be a film composed of a metal element such as a copper film (Cu film), a tungsten film (W film), a ruthenium film (Ru film), a cobalt film (Co film), or a molybdenum film (Mo film). At least one of these films may be used as the second base.

Further, in the above-described embodiments, an example where the above-described processing sequence is performed in the same process chamber of the same processing apparatus (in-situ) is described. The present disclosure is not limited to the above-described embodiments, and for example, one step and another step of the above-described processing sequence may be performed respectively in different process chambers of different processing apparatuses (ex-situ) or may be performed respectively in different process chambers of the same processing apparatus. In such cases as well, effects similar to those in the above-described embodiments are obtained.

In the various cases described above, by performing a series of steps in-situ, the wafer 200 may not be exposed to the atmosphere during the processing, which allows the wafer 200 to be processed consistently while keeping the wafer 200 under vacuum, thereby enabling a stable processing of the wafer 200. Further, by performing some steps ex-situ, it is possible to set the temperature in each process chamber, for example, close to or at the processing temperature for each step in advance, thereby shortening a time which is taken to regulate the temperature. This enhances a throughput, thereby improving a productivity.

Specifically, the recipes used in each process may be provided individually according to processing contents and may be record and stored in the memory 121c via a telecommunication line or the external memory 123. Further, specifically, at the beginning of each processing, the CPU 121a may properly select an appropriate recipe among a plurality of recipes recorded and stored in the memory 121c according to the processing contents. Thus, it is possible to form films of various types, composition ratios, qualities, and thicknesses with enhanced reproducibility in a processing apparatus. Further, it is possible to reduce an operator's burden, and quickly start each processing while avoiding an operation error.

The recipes mentioned above are not limited to newly-provided ones but may be provided, for example, by modifying existing recipes that are already installed in the processing apparatus. Once the recipes are modified, the modified recipes may be installed in the processing apparatus via a telecommunication line or a recording medium storing the recipes. In addition, the existing recipes already installed in the existing processing apparatus may be directly modified by operating the input/output device 122 of the processing apparatus.

An example in which a film is formed by using a batch-type processing apparatus configured to process a plurality of substrates at a time is described in the above-described embodiments of the present disclosure. The present disclosure is not limited to the above-described embodiments of the present disclosure, but may be suitably applied, for example, to a case where a film is formed by using a single-wafer type processing apparatus configured to process a single substrate or several substrates at a time. In addition, an example in which a film is formed by using a processing apparatus including a hot-wall-type process furnace is described above in the above-described embodiments. The present disclosure is not limited to the above-described embodiments, but may be suitably applied to a case where a film is formed by using a processing apparatus including a cold-wall-type process furnace.

Even in the case of using these processing apparatuses, each process may be performed according to the same processing procedure and processing condition as those in the above-described embodiments and modifications, and the same effects as the above-described embodiments and modifications are achieved.

The above-described embodiments and modifications may be used in proper combination. The processing procedure and processing condition used in this case may be the same as, for example, those in the above-described embodiments and modifications.

According to the present disclosure in some embodiments, it is possible to selectively form a film on a desired surface with high precision.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method comprising:
(a) forming a first film containing a first element and a second element on a surface of a first base by supplying a first film-forming agent to a substrate including the first base and a second base;
(b) forming an inhibitor layer on the first film by supplying a modifying agent to the substrate and causing at least a portion of molecular structures of molecules constituting the modifying agent to be adsorbed on the first film; and
(c) forming a second film containing the first element and the second element on a surface of the second base by supplying a second film-forming agent to the substrate with the inhibitor layer formed on the first film.

2. The processing method of claim 1, wherein the first film is an oxide film and the second film is an oxide film.

3. The processing method of claim 1, wherein the first element is silicon and the second element is oxygen.

4. The processing method of claim 3, wherein the first film is a silicon oxide film, a silicon oxycarbide film, or a silicon oxycarbonitride film, and the second film is a silicon oxide film, a silicon oxycarbide film, or a silicon oxycarbonitride film.

5. The processing method of claim 1, wherein the first film and the second film are made of the same material.

6. The processing method of claim 1, wherein in (a), a first precursor and a first oxidizing agent are supplied as the first film-forming agent to the substrate, and
wherein in (c), a second precursor and a second oxidizing agent are supplied as the second film-forming agent to the substrate.

7. The processing method of claim 6, wherein in (a), a cycle is performed a predetermined number of times, the cycle including (a1) supplying the first precursor to the substrate and (a2) supplying the first oxidizing agent to the substrate, and
wherein in (c), a cycle is performed a predetermined number of times, the cycle including (c1) supplying the second precursor to the substrate and (c2) supplying the second oxidizing agent to the substrate.

8. The processing method of claim 7, wherein a first catalyst is further supplied in at least one selected from the group of (a1) and (a2), and
wherein a second catalyst is further supplied in at least one selected from the group of (c1) and (c2).

9. The processing method of claim 6, wherein the first precursor and the second precursor are substances containing at least one selected from the group of an amino group, an alkoxy group, and a chloro group, and the first oxidizing agent and the second oxidizing agent are substances containing oxygen and hydrogen.

10. The processing method of claim 6, wherein the first precursor and the second precursor are the same substance, and the first oxidizing agent and the second oxidizing agent are the same substance.

11. The processing method of claim 1, wherein a thickness of the first film is less than or equal to a thickness of the second film.

12. The processing method of claim 1, wherein (a) is performed under a processing condition with a lower film formation rate than (c).

13. The processing method of claim 1, wherein a temperature of the substrate is the same in (a), (b), and (c).

14. The processing method of claim 1, wherein (a), (b), and (c) are performed in the same space.

15. The processing method of claim 1, further comprising (d) removing the first film by supplying an etching agent to the substrate after forming the second film on the surface of the second base.

16. The processing method of claim 1, further comprising (e) forming a third film on the second film by supplying a third film-forming agent to the substrate after forming the second film.

17. The processing method of claim 1, wherein the first base includes an insulating film, and the second base includes at least one selected from the group of a semiconductor substrate, a film composed of a semiconductor element, and a film composed of a metal element.

18. A method of manufacturing a semiconductor device, comprising the processing method of claim 1.

19. A processing apparatus comprising:
a first film-forming agent supply system configured to supply a first film-forming agent to a substrate;
a modifying agent supply system configured to supply a modifying agent to the substrate;
a second film-forming agent supply system configured to supply a second film-forming agent to the substrate; and
a controller configured to be capable of controlling the first film-forming agent supply system, the modifying agent supply system, and the second film-forming agent supply system to perform a process including:
(a) forming a first film containing a first element and a second element on a surface of a first base by supplying the first film-forming agent to the substrate including the first base and a second base;
(b) forming an inhibitor layer on the first film by supplying the modifying agent to the substrate and causing at least a portion of molecular structures of molecules constituting the modifying agent to be adsorbed on the first film; and
(c) forming a second film containing the first element and the second element on a surface of the second base by supplying the second film-forming agent to the substrate with the inhibitor layer formed on the first film.

20. A non-transitory computer-readable recording medium storing a program that causes, by a computer, a processing apparatus to perform a process comprising:
(a) forming a first film containing a first element and a second element on a surface of a first base by supplying a first film-forming agent to a substrate including the first base and a second base;
(b) forming an inhibitor layer on the first film by supplying a modifying agent to the substrate and causing at least a portion of molecular structures of molecules constituting the modifying agent to be adsorbed on the first film; and
(c) forming a second film containing the first element and the second element on a surface of the second base by supplying a second film-forming agent to the substrate with the inhibitor layer formed on the first film.
